(19) United States
(12) Patent Application Publication
(10) Pub. No.: US 2012/0022687 A1
(43) Pub. Date: Jan. 26, 2012

(54) METHOD FOR TRANSFERRING CHIP AND APPARATUS FOR TRANSFERRING CHIP

(75) Inventors: Ji-Huei Chen, Hsinchu County (TW); Hsiang-Jung Chung, Hsinchu County (TW)

(73) Assignee: LEXTAR ELECTRONICS CORP., Hsinchu (TW)

(21) Appl. No.: 12/943,028

(22) Filed: Nov. 10, 2010

(30) Foreign Application Priority Data
Jul. 21, 2010 (TW) 99124003

(51) Int. Cl. H01L 21/677; G06F 19/00

(52) U.S. Cl. 700/245; 414/800

(57) ABSTRACT

A method for transferring chips is provided for fixing one of the chips on a blue tape without sorting. A blue tape, a plurality of chips disposed thereon and a mapping data are provided, wherein the chips are disposed on the same blue tape, belong to the same wafer, and belong to a plurality of specifications. The specifications include a first specification and a second specification. The mapping data include the specifications the chips belonging to and the positions of the chips relative to the blue tape. According the mapping data, the chips belonging to the first specification are moved from the blue tape and fixed to a package carrier corresponding to the first specification. According the mapping data, the chips belonging to the second specification are moved from the blue tape and fixed to a package carrier corresponding to the second specification. A chip transferring apparatus is also provided.

### CROSS-REFERENCE TO RELATED APPLICATION

This application claims the priority benefit of Taiwan application serial no. 99124003, filed on Jul. 21, 2010. The entirety of the above-mentioned patent application is hereby incorporated by reference herein and made a part of this specification.

### BACKGROUND OF THE INVENTION

1. Field of the Invention

The invention relates to a chip transferring technique and more particularly to a method for transferring chip and an apparatus for transferring chip.

2. Description of Related Art

Light emitting diodes (LEDs) have advantages including long life span, small volume, high vibration resistance, low heating value, and low power consumption. As a consequence, LEDs are now applied in indicators of electronic products, backlight sources of liquid crystal displays (LCDs), traffic lights, large display boards, and illumination light sources. From a manufacturing perspective, the manufacture of LEDs includes a preceding chip manufacture and a following chip packaging.

FIG. 1 illustrates a conventional method of transferring chips. Referring to FIG. 1, as shown in step S12, a testing step is performed; that is, the photoelectric property of a plurality of LED chips disposed on a blue tape, belongs to the same wafer, and unsorted is tested to generate a mapping data. Here, the mapping data include the position and the specification of each of the chips. Next, as illustrated in step S14, a sorting step is performed. In other words, the chips with the same specification (that is, similar photoelectric properties) and on different blue tapes respectively are moved to another blue tape according to the mapping data, so that the same blue tape includes the chips with the same specification. Thereafter, a wafer expanding step is performed as depicted in step S16. That is, the blue tape is extended to increase the distance between the chips for facilitating chip collection. Finally, as shown in step S18, a chip fixing step is carried out. The chips sorted to the same specification are transferred from the same blue tape and fixed to a package carrier corresponding to the same specification. The package carrier is a leadframe or a wiring substrate, for instance.

It should be noted that in the method aforementioned, the LED chips undergo the blue tape twice from the testing step to the chip fixing step, that is each LED chip undergoes two different blue tapes before and after the sorting step. However, the used and non-recyclable blue tapes are unfavorable to cost reduction and environment protection. Besides, that each LED chip transferred between the blue tapes twice increases the possibility of dislocation.

### SUMMARY OF THE INVENTION

The invention is directed to a method of transferring chips for transferring chips to package carriers.

The invention is directed to a chip transferring apparatus for transferring chips to package carriers.

The invention is directed to a method of transferring chips to provide a process of fixing one of the chips on a blue tape without sorting. A blue tape, a plurality of chips disposed thereon, and a mapping data are provided. The chips are disposed on the same blue tape, belong to the same wafer, and belong to a plurality of specifications. The specifications include a first specification and a second specification. The mapping data include the specifications the chips belonging to and positions of the chips relative to the blue tape. According the mapping data, the chips belonging to the first specification are moved from the blue tape and fixed to a package carrier corresponding to the first specification. According the mapping data, the chips sorted to the second specification are moved from the blue tape and fixed to a package carrier corresponding to the second specification.

The invention is directed to a chip transferring apparatus including the following components. A platform is included for carrying a blue tape and a plurality of chips, where the chips are disposed on the blue tape. A data bank is provided to store a mapping data. The mapping data include specifications the chips belonging to and positions of the chips relative to the blue tape. A first filling module is provided for storing a plurality of package carriers respectively corresponding to the specifications and supplying the package carrier of the required specification. A second filling module is provided for storing a plurality of package carriers respectively corresponding to the specifications and supplying the package carrier of the required specification. A transmission module is included to transmit the package carriers supplied from the first filling module or the second filling module. A moving module is provided to move the chips from the blue tape to the package carrier of the corresponding specification according to the mapping data.

In light of the foregoing, the method of transferring chips in the invention can reduce cost and be environmental friendly by omitting the conventional sorting step to reduce the use of blue tapes. In addition, the method of transferring chips in the invention can reduce the number of times of transferring each LED chip between different blue tapes so as to reduce the possibility of dislocation. Moreover, the chip transferring apparatus of the invention utilizes a plurality of filling modules in co-operation with a transmission module to provide the package carrier for reducing the time of chip transfer.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 illustrates a conventional method of transferring chips.

FIG. 2 illustrates a method of transferring chips according to an embodiment of the invention.

FIG. 3 illustrates a chip transferring apparatus according to another embodiment of the invention.

### DESCRIPTION OF EMBODIMENTS

The present embodiment discloses a method of transferring chips. Herein, the target to be transferred is a plurality of light emitting diode (LED) chips. The chips are disposed on the same blue tape, belong to the same wafer, and are unsorted. Based on their differences in photoelectric property, the chips belong to different specifications.

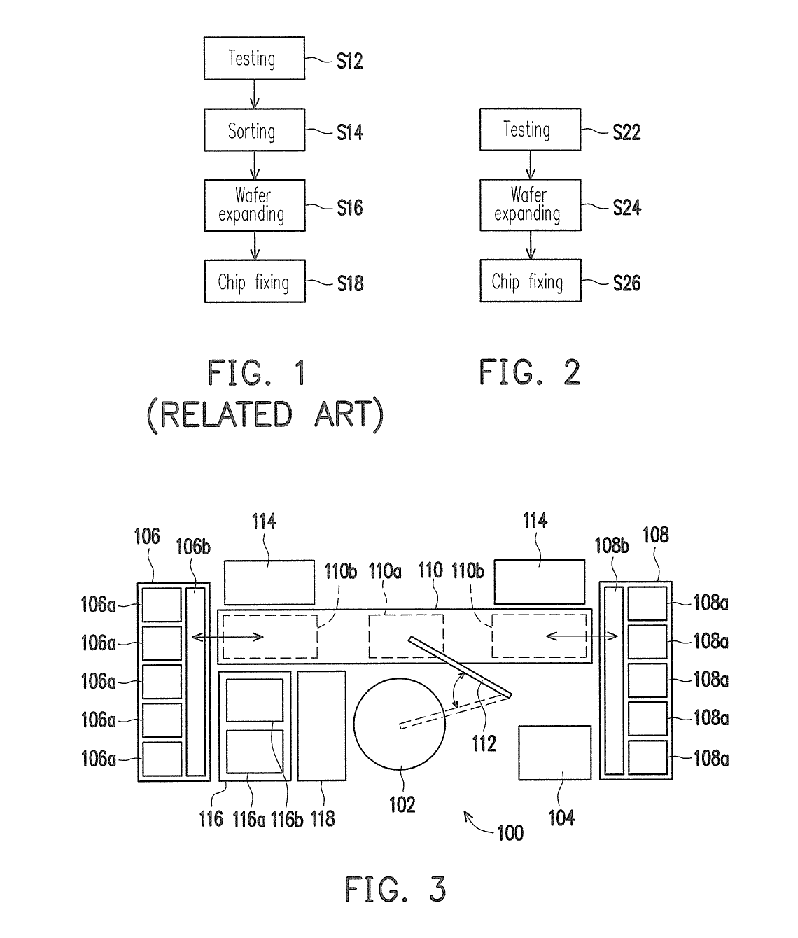

FIG. 2 illustrates a method of transferring chips according to an embodiment of the invention. Referring to FIG. 1, as shown in step S22, a testing step is performed. That is, the photoelectric property of all the chips on the same blue tape is tested to generate a mapping data. The mapping data includes specifications of each of the chips and positions of the chips relative to the blue tape.

In the present embodiment, the testing step further includes an appearance examination of the chips for examining chips with appearances failing to comply with the standard and eliminating these chips from the targets to be moved. The appearance examination results are also recorded in the mapping data.

As depicted in step S24, a wafer expanding step is performed. That is, the blue tape is extended to increase the distance between the chips for facilitating chip collection.

Afterwards, a chip fixing step is carried out as shown in step S26. The chips belonging to the same specification are moved from the blue tape and fixed to a package carrier corresponding to this specification according to the mapping data. In other words, the chips belonging to a first specification are moved and fixed to a package carrier corresponding to the first specification. The chips belonging to the second specification are moved and fixed to a package carrier corresponding to a second specification. The rest is moved, and fixed in a similar manner.

In the present embodiment, the step of fixing the chips to the package carrier includes fixing the chips to the package carrier with an adhesive.

In the present embodiment, the package carrier corresponding to the same specification includes a plurality of carrier elements. The chips belonging to the same specification are fixed to the carrier elements respectively.

In the present embodiment, a mark is formed on each package carrier, and then the markers on the package carriers are further identified to update a carrier data. The carrier data include storing positions of the package carriers, corresponding specifications of the package carriers, and whether the package carriers are installed with the chips. The above markers are barcodes that can be optically identified, for example.

It should be illustrated that from the testing step to the chip fixing step in the present embodiment, the chips are moved and fixed directly according to the mapping data in the chip fixing step. Thus, the sorting step S14 shown in FIG. 1 can be omitted, and the LED chips merely undergo the blue tape once. Comparing to the conventional method requiring for twice of blue tapes, the present embodiment facilitates in reducing cost and is environment friendly, and reduces the number of times of transferring each LED chip between different blue tapes so as to reduce the possibility of dislocation.

FIG. 3 illustrates a chip transferring apparatus according to another embodiment of the invention. Referring to FIG. 2, a chip transferring apparatus 100 of the present embodiment includes a platform 102 configured for carrying a blue tape and a plurality of chips disposed thereon. The chips belong to the same wafer and include corresponding specifications according to their photoelectric properties.

The chip transferring apparatus 100 further includes a data bank 104 to store a mapping data. The mapping data include specifications the chips belonging to and positions of the chips relative to the blue tape.

The chip transferring apparatus 100 further includes a first filling module 106 configured to store a plurality of package carriers respectively corresponding to the specifications belonging to the chips and supply the package carrier of the required specification. Additionally, the chip transferring apparatus 100 further includes a second filling module 108 configured to store a plurality of package carriers respectively corresponding to the specifications belonging to the chips and supply the package carrier of the required specification.

The chip transferring apparatus 100 further includes a transmission module 110 configured to move the package carriers supplied from the first filling module 106 or the second filling module 108. In the present embodiment, the transmission module 110 is a single rail transmission module or a single band transmission module. The transmission module 110 may includes a fixing area 110a for parking the package carriers temporarily.

In the present embodiment, the transmission module 110 moves the package carrier already installed with the chips of the same specification and a package carrier to be installed with the chips of the same or another specification in parallel timing. Consequently, the time for transferring these chips on the same blue tape can be reduced to increase production.

In another embodiment not illustrated herein, the chip transferring apparatus 100 includes two or more filling modules and the transmission module 110 also moves the package carriers supplied from the filling modules. For example, when a package carrier of specification A is to be used, the package carrier of specification A is input by transmission module 110. Thereafter, when a package carrier of specification B is to be used, the package carrier of specification A is output by the transmission module 110 and the package carrier of specification B is also input by the transmission module 110.

The chip transferring apparatus 100 further includes a moving module 112 for moving the chips from the blue tape to the package carrier of the corresponding specification according to the mapping data. In the present embodiment, the moving module 112 moves the chips from the platform 102 to the package carrier located in the fixing area 110a of the transmission module 110. Moreover, in the present embodiment, the moving module 112 is a robotic module.

Therefore, according to the mapping data in the data bank 104, the first filling module 106 or the second filling module 118 provides the package carrier corresponding to the specification of the chips to the transmission module 110, and moves the chips disposed on the platform 102 and to be moved to the package carrier on the transmission module 110 through the moving module 112.

To provide the package carrier corresponding to the specification of the chips, the data bank 104 further stores a package carrier data. The package carrier data include storing positions of the package carriers, corresponding specifications of the package carriers, and whether the package carriers are installed with the chips. Thus, an apparatus in the following packaging process can access the package carrier data in the data bank 104 through a data transmission system so as to acquire the chip specification of each of the package carrier fixed with the chips.

In order to store the package carriers corresponding to different chip specifications, the first filling module 106 includes a plurality of cartridges 106a, where each one of the cartridges 106a stores the package carriers corresponding to the same chip specification. Furthermore, the second filling module 108 also includes a plurality of cartridges 108a, and one of the cartridges 108 stores the package carriers corresponding to the same chip specification.

In order to move the package carrier from a cartridge 106a to the transmission module 110, the first filling module 106 includes a moving device 106b for moving the package carrier from the corresponding cartridge 106a to the transmission module 110 or moving the package carrier from the transmission module 110 to the corresponding cartridge 106a.

In order to move the package carrier from the cartridge 108a to the transmission module 110, the second filling module 108 includes a moving device 108b for moving the package carrier from the corresponding cartridge 108a to the transmission module 110 or moving the package carrier from the transmission module 110 to the corresponding cartridge 108a.

In order to fix the chips moved from the platform 102 to the package carrier, the chip transferring apparatus 100 further includes a plurality of adhesive dispensing modules 114. The transmission module 110 further includes a plurality of adhesive dispensing areas 110b. These adhesive dispensing areas 110b are located on outer sides of the fixing area 110a respectively. The adhesive dispensing modules 114 perform an adhesive dispensing to the package carriers located on the adhesive dispensing areas 110b respectively.

To generate the mapping data from the chips on the same wafer, the chip transferring apparatus 100 further includes a testing module 116 for pre-testing the chips to establish the mapping data.

In the present embodiment, the testing module 116 includes a photoelectric property testing unit 116a to sort the chips to particular specifications according to their photoelectric properties. Moreover, the testing module 116 further includes an appearance examining unit 116b for examining the chips with appearances failing to comply with the standard and eliminating these chips from the targets to be moved. The appearance examination results are also recorded in the mapping data.

In the present embodiment, the chip transferring apparatus 100 further includes a supplying module 118 to move the tested wafer (chips) and the blue tape underneath from the testing module 116 to the platform 102.

In summary, the method of transferring chips in the invention reduces cost and is environmental friendly by omitting the conventional sorting step to reduce the use of blue tapes. In addition, the method of transferring chips in the invention can reduce the number of times of transferring each LED chip between different blue tapes so as to reduce the possibility of dislocation. Moreover, the chip transferring apparatus of the invention utilizes a plurality of filling modules in co-operation with a transmission module to provide the package carrier for reducing the time of chip transfer.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method of transferring chips, adapted for a process of fixing one of the chips on a blue tape without sorting, the method comprising:
providing a blue tape, a plurality of chips disposed thereon, and a mapping data, wherein the chips are disposed on a same blue tape and belong to a same wafer, the specifications comprise a first specification and a second specification, and the mapping data comprise the specifications the chips belonging to and positions of the chips relative to the blue tape;
according the mapping data, moving the chips belonging to the first specification from the blue tape and fixing the chips to a package carrier corresponding to the first specification; and
according the mapping data, moving the chips belonging to the second specification from the blue tape and fixing the chips to a package carrier corresponding to the second specification.

2. The method of transferring chips as claimed in claim 1, wherein the step of providing the mapping data comprises testing the chips to generate the mapping data.

3. The method of transferring chips as claimed in claim 2, wherein the step of testing the chips comprises performing a photoelectric property test.

4. The method of transferring chips as claimed in claim 2, wherein the step of testing the chips comprises performing an appearance examination.

5. The method of transferring chips as claimed in claim 2, further comprising:
extending the blue tape to increase a distance between the chips before moving and fixing the chips.

6. The method of transferring chips as claimed in claim 1, wherein the package carrier corresponding to the first specification comprises a plurality of carrier elements and the chips belonging to the first specification are fixed to the carrier elements respectively.

7. The method of transferring chips as claimed in claim 1, wherein the step of fixing the chips to the package carrier comprises:
fixing the chips to the package carrier with an adhesive.

8. The method of transferring chips as claimed in claim 1, further comprising:
forming a marker on each of the package carriers; and
identifying the markers on the package carriers to update a carrier data, wherein the carrier data comprise storing positions of the package carriers, corresponding specifications of the package carriers, and whether the package carriers are installed with the chips.

9. A chip transferring apparatus, comprising:
a platform, carrying a blue tape and a plurality of chips, wherein the chips are disposed on the blue tape;
a data bank, storing a mapping data, wherein the mapping data comprise specifications the chips belonging to and positions of the chips relative to the blue tape;
a first filling module, storing a plurality of package carriers respectively corresponding to the specifications and supplying the package carrier of a required specification;
a second filling module, storing a plurality of package carriers respectively corresponding to the specifications and supplying the package carrier of a required specification;
a transmission module, transmitting the package carriers supplied from the first filling module or the second filling module; and
a moving module, moving the chips from the blue tape to the package carrier of the corresponding specification according to the mapping data.

10. The chip transferring apparatus as claimed in claim 9, wherein the data bank further stores a package carrier data comprising storing positions of the package carriers, specifications corresponding to the package carriers, and whether the package carriers are installed with the chips.

11. The chip transferring apparatus as claimed in claim 9, wherein the first filling module comprises a plurality of cartridges and a moving device, each of the cartridges stores one of package carriers corresponding to one of the specifications, and the moving device moves the package carrier from the corresponding cartridge to the transmission module or moves the package carrier from the transmission module to the corresponding cartridge.

12. The chip transferring apparatus as claimed in claim 9, wherein the transmission module moves the package carrier already installed with the chips of a same specification and the package carrier to be installed with the chips of a same or another specification simultaneously.

13. The chip transferring apparatus as claimed in claim 9, wherein the transmission module comprises a fixing area and the moving module moves the chip to the package carrier located in the fixing area.

14. The chip transferring apparatus as claimed in claim 13, further comprising:
a plurality of adhesive dispensing modules, wherein the transmission module further comprises a plurality of adhesive dispensing areas located on an outer side of the fixing area, and the adhesive dispensing modules performs an adhesive dispensing to the package carriers located in the adhesive dispensing areas respectively.

15. The chip transferring apparatus as claimed in claim 9, further comprising:
a testing module for testing the chips to establish the mapping data.

16. The chip transferring apparatus as claimed in claim 15, wherein the testing module comprises a photoelectric property testing unit.

17. The chip transferring apparatus as claimed in claim 15, wherein the testing module comprises an appearance examining unit.

18. The chip transferring apparatus as claimed in claim 9, further comprising:
a supplying module, moving the chips tested and the blue tape underneath from the testing module to the platform.

19. The chip transferring apparatus as claimed in claim 9, wherein the transmission module is a single rail transmission module or a single band transmission module.

20. The chip transferring apparatus as claimed in claim 9, wherein the moving module is a robotic module.
